(19) United States
(12) Patent Application Publication
(10) Pub. No.: US 2009/0294114 A1
(43) Pub. Date: Dec. 3, 2009

(54) HEAT DISSIPATION DEVICE AND MANUFACTURING METHOD THEREOF

(75) Inventors: Ming Yang, Shenzhen City (CN); Xu-Jun Zhong, Shenzhen City (CN); Shou-Li Zhu, Shenzhen City (CN); Qing-Lei Guo, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 12/430,844

(22) Filed: Apr. 27, 2009

(30) Foreign Application Priority Data
May 28, 2008 (CN) 200810067519.6

(51) Int. Cl. F28D 21/00; F28D 15/02; H05K 7/20; B21D 53/02

(52) U.S. Cl. 165/185; 165/104.34; 29/890.03; 29/890.032

(57) ABSTRACT

A heat dissipation device includes a heat pipe and a heat sink. The heat pipe includes an evaporator section and a rectangular condenser section extending from one end of the evaporator section and surrounding the evaporator section. The heat sink includes a main body and a plurality of fins extending outwardly from four lateral sides of the main body. The main body defines a groove on an end surface thereof for receiving the evaporator section therein. Each of the fins includes a plate-shaped body and a flange extending perpendicularly from an end of the plate-shaped body. The top flanges cooperatively form a rectangular supporting surface for supporting the condenser section thereon. The supporting surface is lower than the end surface of the main body.

### BACKGROUND

1. Technical Field

The disclosure relates to heat dissipation, and particularly to a heat dissipation device for dissipating heat generated by an electronic component and a manufacturing method of the heat dissipation device.

2. Description of Related Art

Electronic components operating at high speed generate excessive heat which must be removed efficiently to ensure normal operation. Typically, a heat dissipation device attached to the electronic component provides such heat dissipation.

A conventional heat dissipation device includes a metal base for contacting and absorbing heat from the electronic component, a straight heat pipe with an evaporator section attached to the base, and a heat sink including a plurality fins attached to a condenser section of the heat pipe. By this configuration, firstly, the heat generated by the electronic component is conducted to the base, and then transferred to the heat sink through the heat pipe, and finally is dissipated to ambient by the fins.

For enhancing a heat dissipation effectiveness of the heat dissipation device, a heat dissipation area of the heat sink is greatly increased. However, a heat contacting area between the heat pipe and the heat sink, severely restricted by the straight configuration of the heat pipe, is constant. Thus, most of heat of the electronic component absorbed by the evaporator section of the heat pipe can not be transferred to the heat sink timely, which, therefore, limits the heat dissipation effectiveness of the heat dissipation device.

It is thus desirable to provide a heat dissipation device which can overcome the described limitations.

### BRIEF DESCRIPTION OF THE DRAWINGS

FIG. 1 is an isometric, assembled view of a heat dissipation device according to a first embodiment.

FIG. 2 is an exploded view of the heat dissipation device of FIG. 1.

FIG. 3 is an isometric, assembled view of a heat dissipation device according to a second embodiment.

FIG. 4 is a schematic view of a rudimentary heat sink for manufacturing the present heat dissipation device.

### DETAILED DESCRIPTION

Reference will now be made to the drawing figures to describe the present heat dissipation device in detail.

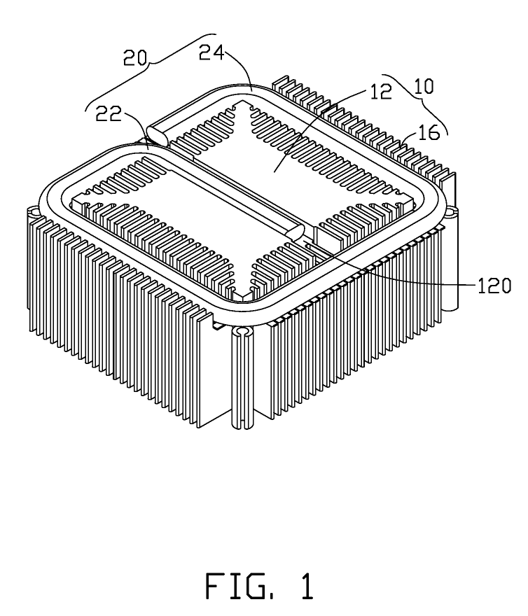

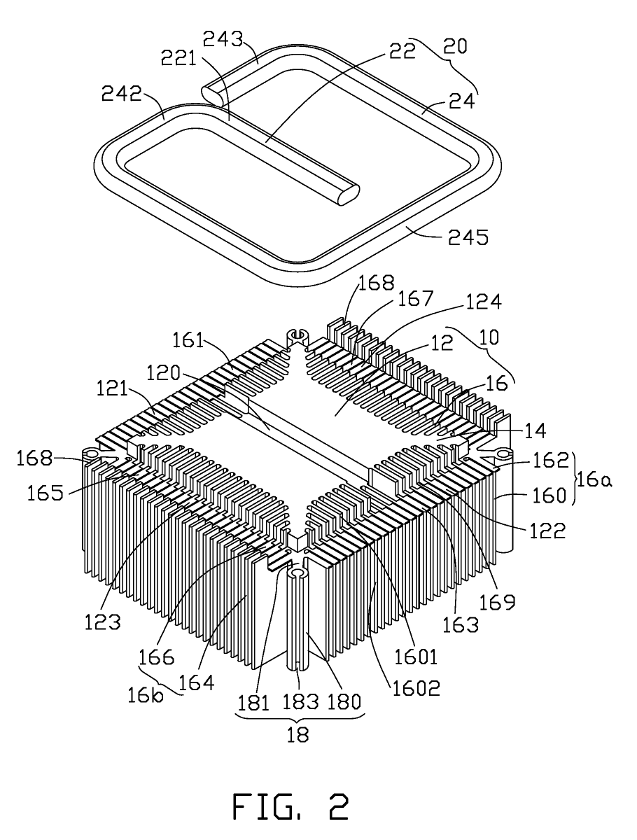

FIGS. 1-2 illustrate a heat dissipation device for dissipating heat generated by an electronic component (not shown). The heat dissipation device includes a heat sink 10 and a heat pipe 20.

The heat pipe 20 includes a straight evaporator section 22 and a condenser section 24 extending outwardly from a connecting end 221 of the evaporator section 22 to form a rectangle which encircles the evaporator section 22 therein. The condenser section 24 includes a fixed portion 242 connected with the connecting end 221 of the evaporator section 22, a free portion 243 adjacent to the connecting end 221 of the evaporator section 22 and a U-shaped middle portion 245 between the fixed portion 242 and the free portion 243. The fixed portion 242 is located at a front side of the evaporator section 22. The free portion 243 is located at a rear side of the evaporator section 22. The fixed portion 242 is substantially collinear with the free portion 243, and is substantially perpendicular to the evaporator section 22. The evaporator section 22 and the condenser section 24 are coplanar.

The heat sink 10 in whole has a substantially rectangular configuration. The heat sink 10 includes a main body 12, a plurality of aluminum extrusion fins 16 extending outwardly from each of four sides of the main body 12, and four mounting posts 18 formed at fours corners of the heat sink 10, respectively. The main body 12 is a quadrangular prism with four protruding portions 14 extending outwardly from four corners thereof towards the four mounting posts 18, respectively. The main body 12 has an approximately rectangular top surface for contacting the electronic component to absorb heat therefrom. A groove 120 is defined at a middle portion of the top surface of the main body 12. The groove 120 extends along a centerline of the top surface of the main body 12, and connects two opposite sides, i.e. a left side and a right side, of the top surface. The centerline of the main body 12 divides the heat sink 10 into symmetrical front and rear portions. The groove 120 has a size substantially equals to a size of the evaporator section 22 of the heat pipe 20.

The fins 16 includes a plurality of first fins 16a located at a left side and a right side of the main body 12, respectively, and a plurality of second fins 16b located at a front side and a rear side of the main body 12, respectively. The first fins 16a are parallel to each other, and are perpendicular to the left and the right sides of the heat sink 10. The second fins 16b are parallel to each other, and are perpendicular to the front and the rear sides of the heat sink 10. Thus, the first fins 16a are perpendicular to the second fins 16b.

Each first fin 16a has a plate-shaped body 160 and an upper flange 162. The plate-shaped body 160 includes an inner portion 1601 connected to the main body 12 and an outer portion 1602 extending outwardly from the inner portion 1601. Each of the outer portions 1602 defines a cutout 169 at a top end thereof, and thus the outer portion 1602 has a height lower than that of the inner portion 1601. Cooperatively, the cutouts 169 at the left side of the heat sink 10 define a first slot 121 over the outer portions 1602 of the left first fins 16a. Similarly, the cutouts 169 at the right side of the heat sink 10 define a second slot 122 over the outer portions 1602 of the right first fins 16a. Each of the upper flanges 162 extends perpendicularly from the top end of the outer portion 1602 of the plate-shaped body 160 to a neighboring plate-shaped body 160 of the first fin 16a. The upper flanges 162 of the left first fins 16a cooperatively form a first surface 161 at the left side of the heat sink 10. The first surface 161 is perpendicular to the groove 120 and communicates with a left end of the groove 120. Similarly, the upper flanges 162 of the right first fins 16a cooperatively form a second surface 163 at the right side of the heat sink 10. The second surface 163 is perpendicular to the groove 120 and communicates with a right end of the groove 120.

Each of the second fins 16b has a plate-shaped body 164 and an upper flange 166. Each of the upper flanges 166 extends perpendicularly from a middle portion of a top end of the plate-shaped body 164 to a neighboring plate-shaped body 164. The middle portion of each plate-shaped body 164 is lower than other portion of the plate-shaped body 164. A third slot 123 is thus formed over the upper flanges 166 of the front second fins 16b. Similarly, a fourth slot 124 is formed over the upper flanges 166 of the rear second fins 16b. The third slot 123 communicates front ends of the first and the second slots 121, 122, and the fourth slot 124 communicates rear ends of the first and the second slots 121, 122. An outer portion of the top end of the plate-shaped body 164 of the front second fin 16b form a first barrier 168 at an outside of the third slot 123. Similarly, an outer portion of the top end of the plate-shaped body 164 of the rear second fin 16b form a second barrier 168 at an outside of the fourth slot 124. The upper flanges 166 of the front second fins 16b cooperatively form a third surface 165 below the first slot 123 and located at a front side of the groove 120. Similarly, the upper flanges 166 of the rear second fins 16b cooperatively form a fourth surface 167 below the fourth slot 124 and located at a rear side of the groove 120. The first, second, third and fourth surfaces 161, 163, 165, 167 are coplanar to form a rectangular supporting surface surrounding the groove 120 of the main body 12. The supporting surface is level with the top surface of the main body 120 defining the groove 120, and is provided for supporting the condenser section 24 of the heat pipe 20 thereon. The first, second, third and fourth slots 121, 122, 123, 124 cooperatively form a receiving channel over the supporting surface for accommodating the condensing section 24 of the heat pipe 20 therein. A depth of the receiving channel is substantially the same as a thickness of the heat pipe 20. The first and second barriers 168 are arranged at a front side and a rear side of the receiving channel, respectively, for reliably and firmly positioning the condenser section 24 of the heat pipe 20 on the supporting surface.

Each of the mounting posts 18 includes an arm 181 connected with a corresponding protruding portion 14 of the main body 12 and a forficate portion 180 formed at a free end of the arm 181. The forficate portion 180 is cylindrical with an opening 183 defined at a distal side thereof.

When assembled, the evaporator section 22 of the heat pipe 20 is mounted in the groove 120 of the top surface of the main body 12, and the condenser section 24 is mounted in the receiving channel for thermally contacting with the fins 16. More specifically, the fixed portion 242 and the free portion 243 of the condenser section 24 are located on the first surface 161 for thermally contacting with the left first fins 16a, and the U-shaped middle portion 245 of the condenser section 24 is located on the second, the third and the fourth surfaces 163, 165, 167 for thermally contacting with the front second fins 16b, the right first fins 16a and the rear second fins 16b. Preferably, the heat pipe 20 is tabular and has a planar bottom surface for providing a large contacting area between the heat pipe 20 and the fins 16. The electronic component is arranged on the top surface of the main body 12 and contacts the evaporator section 22 of the heat pipe 20 closely. Fasteners respectively traverse through the forficate portions 180 of the mounting posts 18 and engage into a circuit board on which the electronic component is mounted, for maintaining a firmly contacting between the electronic component and the heat dissipation device.

During operation, the top surface of the main body 12 and the evaporator section 22 of the heat pipe 20 absorb heat from the electronic component; the heat is spread on the main body 12 and the fins 16 around the main body 12 via the top surface of the main body 12 and the heat pipe 20 quickly; and finally the heat is dissipated to ambient air via the fins 16. Since the condenser section 24 of the heat pipe 20 includes the fixed portion 242, the free portion 243 and the U-shaped middle portion 245 which are fully in thermal contact with the fins 16 formed around four sides of the main body 12, respectively, a large heat contacting area between the heat pipe 20 and heat sink 10 is provided. The heat pipe 20 has excellent heat transfer performance due to their low thermal resistance, and therefore a large amount of heat generated by the electronic component is absorbed by the evaporator section 22 of the heat pipe 20 and is quickly and effectively transferred to different portions of the heat sink 10 far from the electronic component, via the large heat contacting area between the condenser section 24 of the heat pipe 20 and the heat sink 10. Accordingly, the heat dissipation efficiency of the heat dissipation device is improved.

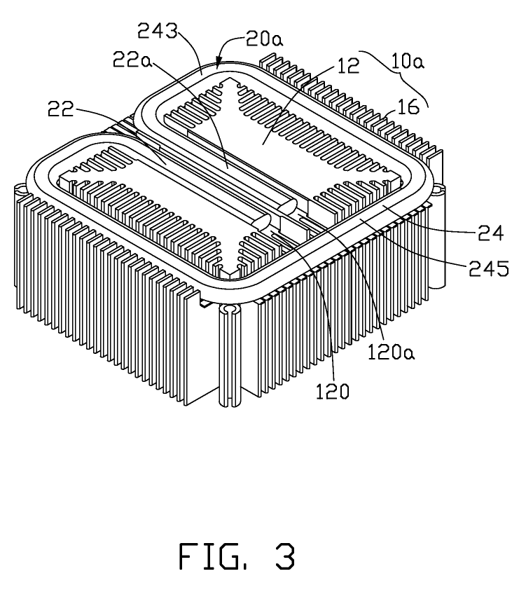

FIG. 3 is an assembled view of a heat dissipation device in accordance with a second embodiment of the disclosure, differing from the previous embodiment only in that a heat pipe 20a includes two evaporator sections, i.e., a first evaporator section 22 and a second evaporator section 22a. The two evaporator sections 22, 22a are parallel to each other, and are located adjacent to each other. The heat sink 10a defines a pair of parallel grooves 120, 120a on the top surface of the main body 12 for receiving the evaporator sections 22, 22a therein. The second evaporator section 22a extends perpendicularly from the free portion 243 of the condenser section 24 towards the middle portion 245. During operation, heat can be absorbed by both of the first evaporator section 22 and the second evaporator section 22a of the heat pipe 20a simultaneously, and then is quickly and effectively transferred to different portions of the heat sink 10a far from the electronic component via the condenser section 24. Accordingly, the heat is dissipated to ambient air more effectively.

A method of manufacturing the heat dissipation device includes the following steps.

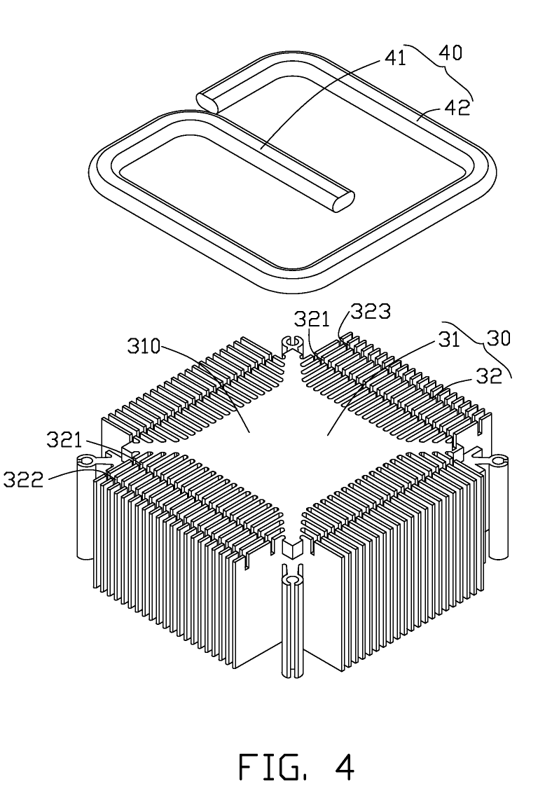

Referring to FIG. 4, firstly, a rudimentary heat sink 30 formed by extrusion molding of aluminum and a heat pipe 40 are provided. The heat pipe 40 has the same configuration as the heat pipe 20 of the first embodiment. The heat pipe 40 includes an evaporator section 41 and a condenser section 42 surrounding the evaporator section 41. Alternatively, the heat pipe 40 can be the heat pipe 20a of the second embodiment. The rudimentary heat sink 30 includes a main body 31 and a plurality of spaced fins 32 extending outwardly from four sides of the main body 31, respectively. The rudimentary heat sink 30 differing from the previous heat sink 10 only in that the main body 31 has a planar top surface 310, and a top end of each of the fins 32 is flat and coplanar with the top surface 310 of the main body 31.

Then a rectangular first slit 321 is defined in the top ends of the fins 32 via a milling process. A depth of the first slit 321 substantially equals to a thickness of the condenser section 42 of the heat pipe 42. In other words, the depth of the first slit 321 is substantially equal to that of each of the first, second, third and fourth slots 121, 122, 123, 124 of the heat sink 10 of FIG. 2. The first slit 321 is located immediately adjacent to the inner portions 1601 of the fins 16 of the heat sink 10 of FIG. 2. A second slit 322 is defined in the top ends of the front fins 32 at a position spaced from the first slit 321 with a distance substantially equals to a width of the third slot 123 of the heat sink 10 of FIG. 2. Similarly, a third slit 323 is defined in the top ends of the rear fins 32 at a position spaced from the first slit 321 with a distance substantially equal to a width of the forth slot 124 of the heat sink 10 of FIG. 2.

Then, the flanges 162 of the heat sink 10 of FIG. 2 are formed by bending the top ends of the right and left fins 32 outside the first slit 321 rearwards and forwardly. The flanges 166 of the heat sink 10 of FIG. 2 are formed by bending the top ends of the front and rear fins 32 between the first and second slits 321, 322 and between the first and third slits 321, 323 leftwards and rightwards. The plurality of the flanges 162, 166 cooperatively form the surfaces 161, 163, 165, 167 of the heat sink 10 of FIG. 2 for supporting the condenser section 42 of the heat pipe 40 thereon.

During the milling process, the groove 120 of the heat sink 10 of FIG. 2, which has a size and shape substantially equal to that of the evaporator section 41 of the heat pipe 40, is defined in the top surface 310 of the main body 31. Accordingly, the heat sink 10 of FIG. 2 is obtained from the rudimentary heat sink 30 of FIG. 4.

Finally, the heat pipe 40 is assembled to the heat sink 10 by soldering, with the evaporator section 41 received in the groove 120 of the main body 12 and the condenser section 42 contacted the flanges 162, 166 of the fins 16 at four sides of the main body 12. Alternatively, the top surface 310 of the main body 31 can be machined to define the grooves 120, 120a of FIG. 3 therein, whereby the heat sink 10a can be obtained and used to accommodate the heat pipe 20a of FIG. 3 therein.

It is to be understood, however, that even though numerous characteristics and advantages of the disclosure have been set forth in the foregoing description, together with details of the structure and function of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipation device comprising:
a heat pipe comprising at least an evaporator section and a rectangular condenser section extending from one end of the at least an evaporator section and surrounding the at least an evaporator section; and
a heat sink comprising a main body and a plurality of fins extending outwardly from four lateral sides of the main body, the main body defining an at least a groove on an end surface thereof for receiving the at least an evaporator section therein, each of the fins comprising a plate-shaped body and a flange extending perpendicularly from an end of the plate-shaped body, the flanges cooperatively forming a rectangular supporting surface for supporting the condenser section thereon, the supporting surface being lower than the end surface of the main body.

2. The heat dissipation device as described in claim 1, wherein the at least an evaporator section and the condenser section are coplanar.

3. The heat dissipation device as described in claim 1, wherein the heat sink in whole has a substantially rectangular configuration and comprises four mounting posts at four corners thereof.

4. The heat dissipation device as described in claim 3, wherein each of the mounting posts comprises an arm connected with a corresponding corner of the heat sink and a forficate portion formed at a free end of the arm.

5. The heat dissipation device as described in claim 3, wherein the main body is a quadrangular prism with four protruding portions extending outwardly from four corners of the quadrangular prism to the mounting posts, respectively.

6. The heat dissipation device as described in claim 1, wherein the fins comprises a plurality of first fins and a plurality of second fins, the flange of each first fin being formed at an outer periphery portion of the end of the plate-shaped body, the flange of each second fin being formed at a middle portion of the end of the plate body.

7. The heat dissipation device as described in claim 6, wherein an outer periphery portion at the end of the plate-shaped body of each second fin is higher than the flange of each second fin, and a barrier is formed at an outside of the flange of each second fin for limiting movement of the condenser section of the heat pipe.

8. The heat dissipation device as described in claim 1, wherein the heat pipe includes a pair of parallel evaporator sections, the heat sink defining a pair of grooves at the end surface thereof for receiving the pair of evaporator sections of the heat pipe therein, respectively.

9. The method as described in claim 1, wherein the supporting surface is level with the end surface of the main body defining the at least a groove.

10. A method of manufacturing a heat dissipation device comprising:
providing a heat sink and a heat pipe, the heat sink comprising a main body and a plurality of fins extending outwardly from four lateral surfaces of the main body, the heat pipe comprising at least an evaporator section and a rectangular condenser section surrounding the at least an evaporator section;
forming a first slit located immediately adjacent to inner portions of the fins at top ends of the fins, and a second slit in the top ends of a part of the fins at a position spaced from the first slit with a distance substantially equals a width of the condenser section of the heat pipe;
bending the top ends of the fins at a portion outside the first slit, and the part of the fins at a portion between the first and second slits, respectively, to form a rectangular supporting surface around the main body, the supporting surface being for supporting the condenser section of the heat pipe thereon;
forming at least a groove on an end surface of the main body for receiving the at least an evaporator section of the heat pipe; and
combining the heat pipe to the heat sink with the at least an evaporator section received in the at least a groove of the main body and the condenser section contacted the supporting surface around the main body.

11. The method as described in claim 10, wherein the main body is a quadrangular prism with four protruding portions extending outwardly from four corners of the quadrangular prism respectively, and the fins are formed by extrusion molding of aluminum around the lateral surfaces of the main body.

12. The method as described in claim 10, wherein a depth of each of the first slits and the second slits equals to a thickness of the condenser section of the heat pipe.

13. The method as described in claim 10, wherein the second slit is defined in the part of the fins which extend from two opposite lateral surfaces of the main body, respectively.
